(19) United States
(12) Patent Application Publication
(10) Pub. No.: US 2003/0122558 A1
(43) Pub. Date: Jul. 3, 2003

(54) System and method for measuring photovoltaic cell conductive layer quality and net resistance

(76) Inventor: Peter L. Hacke, Pittsburgh, PA (US)

Correspondence Address: SQUIRE, SANDERS & DEMPSEY L.L.P, 600 HANSEN WAY, PALO ALTO, CA, 94304-1043, US

(21) Appl. No.: 10/033,202

(22) Filed: Dec. 28, 2001

(51) Int. Cl. G01R 27/08

(52) U.S. Cl. 324/693

(57) ABSTRACT

A system for measuring photovoltaic cell conductive layer quality. The system can be integrated into a light IV cell tester and comprises an electrical sourcing and metering unit, capable to be coupled to a conductive layer of a cell via bus bars, and a conductive layer quality tester communicatively coupled to unit. The unit is capable to apply current to and collect current from the conductive layer as well as meter voltage across the layer. The tester comprises an equipment control engine capable to instruct the electrical sourcing and metering unit to apply and collect a current to the conductive layer and to meter voltage across the layer; a data acquisition engine capable to receive metered voltage data from the electrical sourcing and metering unit, and a data analysis engine capable to calculate resistance of the conductive layer based on applied current and metered voltage, and to calculate conductive layer quality based on the calculated resistance.

### TECHNICAL FIELD

This invention relates generally to photovoltaic (PV) cell manufacture, and more particularly, but not exclusively, provides a system and method for measuring PV cell conductive layer quality.

### BACKGROUND

PV cells convert incident solar radiation into electricity. PV cells comprise semiconductor pn junction diodes with the junction located very close to a top cell surface (i.e., the surface facing a light source) or a bottom cell surface. Conventionally, a PV cell may use, first, a conductive layer comprising of a grid structure and/or, second, a conductive layer comprising of a planar sheet structure. Either of these conductive layer configurations are conventionally formed on or near the cell surfaces. Both these structures are conventionally made of metal or other electrically conducting material having geometry and optical properties selected in part for maximization of light into the semiconductor and efficient current collection from the semiconductor. Conventionally, either of these conductive layer types, which may be used on the cell top and bottom, conduct electricity generated by the cell from incident solar radiation to the bus bars. PV cells may also have anti-reflective coatings deposited on top of the conductive layer, making the conductive layer inaccessible after application of the coating(s).

During manufacture of the PV cell, it is important for quality assurance purposes to measure cell conductive layer quality as a poor-quality cell conductive layer may lead to decreased cell efficiency as measured by electricity output. Breakage of thin lines that comprise the first conductive layer or thinning of the sheet structure of the second conductive layer are examples of issues resulting in poor quality conductive layers.

Conventional techniques for measuring cell conductive layer quality during manufacture include human visual inspection, computer vision inspection and measurement of individual conducting lines of a cell. Visual inspection is often inadequate because the human eye may not be able to see small line breaks, such as those that are only 0.01 mm wide. Using an optical microscope increases the ability to inspect the cell conductive layer but may be extremely time consuming.

Computer vision inspection can be quicker and more accurate than human visual inspection. However, computer vision inspection equipment that can view line breaks or other defects that are only 0.01 mm over larges areas may be extremely expensive. Measurement of individual conductive lines is inconvenient because it requires lining up probes on each individual conductive line. Further, for visual, computer vision inspection, and individual measurement it hard to quantify how measured defects will affect overall cell efficiency.

Accordingly, a new system and method for measuring cell conductive layer quality may be needed.

### SUMMARY

The present invention provides a system for measuring PV cell conductive layer quality. The system may be incorporated into an illuminated IV (current/voltage) cell tester. The system comprises a switching unit coupled to probes making contact to a PV cell under test; an electrical source and metering unit coupled to the switching unit; and a conductive layer quality tester communicatively coupled to the sourcing and metering unit and the switching unit. The electrical source and metering unit, via the switching unit, applies a current to a first probe coupled to a contact on a first of at least two bus bars on either face of a PV cell (a bus bar is a conductor collecting electricity from a cell's conducting layer to which contact is made by probes or bonded wire to obtain electricity from the cell) and collects the current via a second probe coupled to a contact on a second bus bar of the PV cell. The source and metering unit, via the switching unit, also measures voltage between a set of probes coupled to the bus bars during current application. The conductive layer quality tester, based on the current applied and measured voltage, calculates overall resistance (Voltage/Current) of the conductive layer, which increases when the conductive layer quality decreases because conductive line breaks and/or conductive layer thinning increases resistance. In this invention, the bus bars are used to effectively distribute the current used for measurement over the portion of conductive layer between the bus bars being probed for obtaining an effective measurement of resistance, and in turn, a quantitative indicator of quality of that conductive layer region.

The present invention further provides a method for measuring conductive layer quality of a PV cell. The method comprises applying a current to a probe coupled to a contact on a bus bar of a cell and collecting that current at a second probe coupled to a contact on a second bus bar; metering the voltage at a set of probes coupled to contacts on the bus bars of the cell; and calculating resistance (Voltage/Current), which increases when conductive layer quality of the PV cell decreases. Further, the method may comprise looking up conductive layer quality in a table or list corresponding to the calculated resistance for the determination of whether that resistivity falls within a desired range.

Accordingly, the system and method may advantageously enable determination of conductive layer quality of a PV cell.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 is a block diagram illustrating a PV cell tester in accordance with an embodiment of the present invention;

FIG. 2 is a block diagram illustrating a PV cell coupled to a switching unit of the PV cell tester of FIG. 1;

FIG. 3 is a block diagram illustrating an example computer in accordance with an embodiment of the invention;

FIG. 4 is a block diagram illustrating details of the control system of the conductive layer quality tester of the cell tester of FIG. 1; and

FIG. 5 is a flowchart illustrating a method for measuring conductive layer quality of a PV cell.

### DETAILED DESCRIPTION OF THE ILLUSTRATED EMBODIMENTS

The following description is provided to enable any person skilled in the art to make and use the invention, and is provided in the context of a particular application and its requirements. Various modifications to the embodiments will be readily apparent to those skilled in the art, and the generic principles defined herein may be applied to other embodiments and applications without departing from the spirit and scope of the invention. Thus, the present invention is not intended to be limited to the embodiments shown, but is to be accorded the widest scope consistent with the principles, features and teachings disclosed herein.

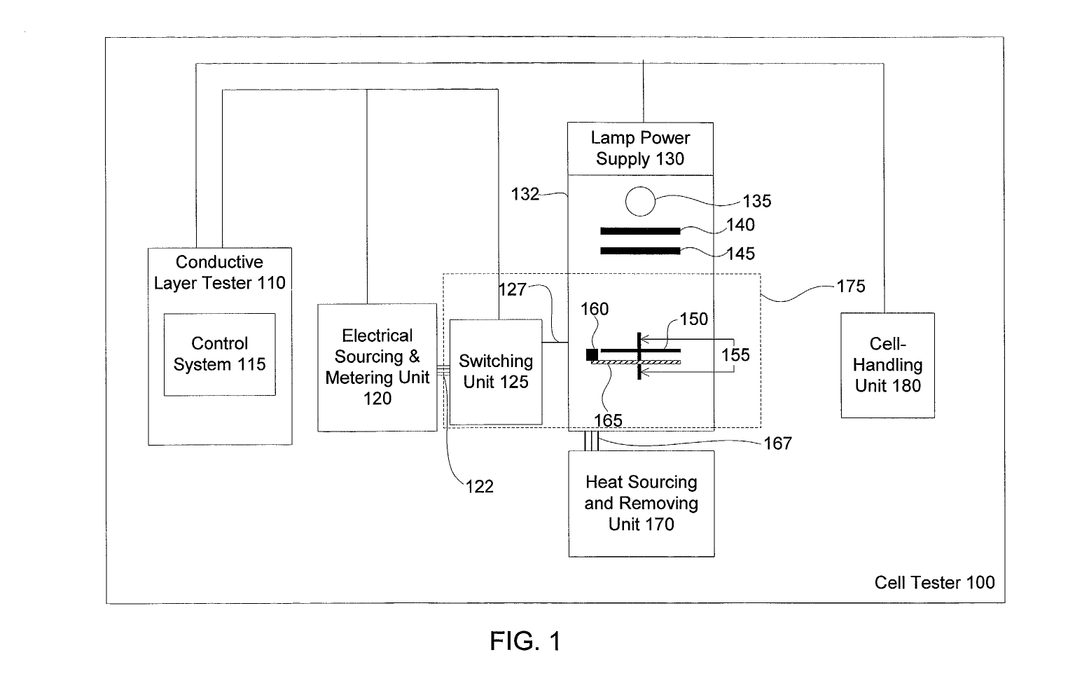

FIG. 1 is a block diagram illustrating an illuminated IV PV cell tester 100 in accordance with an embodiment of the present invention. The PV cell tester 100 comprises a conductive layer tester 110, an electrical sourcing and metering unit 120, a switching unit 125, a testing chamber 132, a heat sourcing and removing unit 170 and a cell-handling unit 180. The conductive layer tester 110 is communicatively coupled to the electrical sourcing and metering unit 120, the switching unit 125, the testing chamber 132, and the cell-handling unit 180. The electrical sourcing and metering unit 120 is coupled to the switching unit 125, which is coupled to a PV cell in testing chamber 132. Further, heat sourcing and removing unit 170 is also coupled to the testing chamber 132.

The conductive layer tester 110 comprises a control system 115 that controls the electrical sourcing and metering unit 120, switching unit 125, testing chamber 132, and cell-handling unit 180. The control system 115 also receives data from the electrical sourcing and metering unit 120 for use in calculating PV cell conductive layer quality.

Electrical sourcing and metering unit 120 is coupled to the switching unit 125 via current/voltage signal lines 122. Unit 120 supplies current, via the switching unit 125, to probes that are coupled to contacts on a cell in the testing chamber 132. The electrical sourcing and metering unit 120, via the switching unit 125, also meters voltage between a set of probes coupled to contacts on the cell. Switching unit 125 enables electrical sourcing and metering unit 120 to apply current to and collect current from specific probes coupled to contacts on the PV cell and to meter voltage between specific probes coupled to contacts on the PV cell.

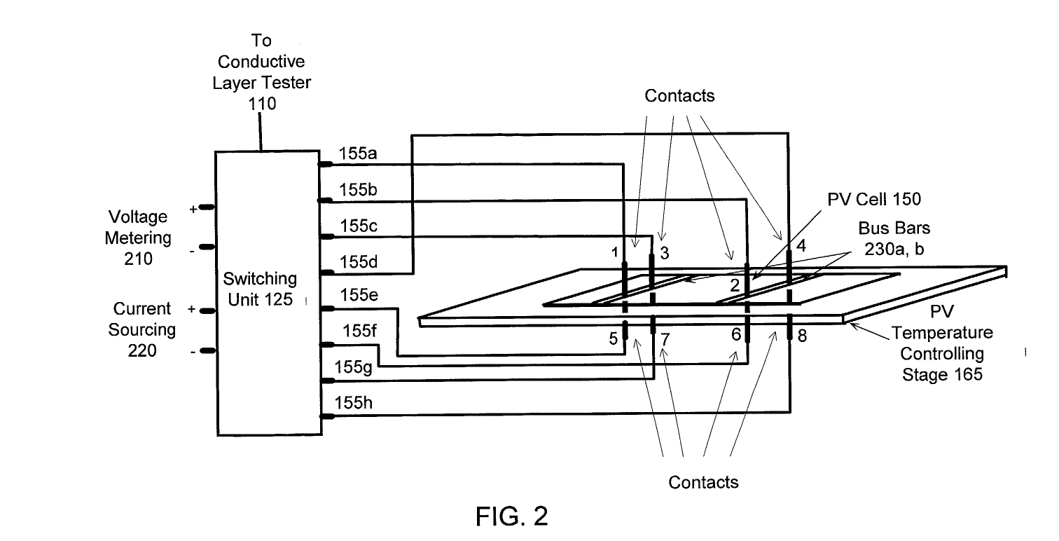

Testing chamber 132 comprises a lamp 135 powered by lamp power supply 135, a light shutter 140, and a light filter/lens 145. Chamber 132 also holds a PV cell, such as cell 150, for testing. Coupled to the PV cell are probes 155 for administering current to and collecting voltage measurements from the PV cell during conductive layer quality testing. Probes 155 will be discussed in further detail in conjunction with FIG. 2. In an embodiment of the invention, chamber 132 may also comprise a reference cell 160 and a temperature and controlling stage 165. Further, a heat sourcing and removing unit 170 may be coupled to the chamber 132 for controlling temperature within the chamber 132.

During conventional cell testing, power supply 130 supplies power to lamp 135, which illuminates a cell, such as cell 150, through shutter 140 and lens 145. Probes 155 can then take lighted IV or dark (current and voltage) measurements. During conductive layer quality testing, probes 155 apply and collect a current to a conductive layer of a cell and simultaneously meter voltage, as will be discussed in further detail in conjunction with FIG. 2. During conductive layer quality testing, lamp 135 need not be used.

Cell handling unit 180, upon receipt of instructions from control system 115, can handle a cell for placement into chamber 132. Further, in an embodiment of the invention, unit 180 can attach probes 155 to contacts on a PV cell for testing.

FIG. 2 is a block diagram illustrating a PV cell 150 coupled to a switching unit 125 of the PV cell tester 100 (FIG. 1). The PV cell comprises contacts 1 and 2 located on the bus bars 230a and 230b, respectively, on a top conductive layer so that applied current will run through a plurality of conducting lines in the top conductive layer of the cell during a conductive layer quality test. Similarly, contacts 3 and 4 are spaced so that voltage can be metered between bus bars 230a and 230b during a conductive layer quality test.

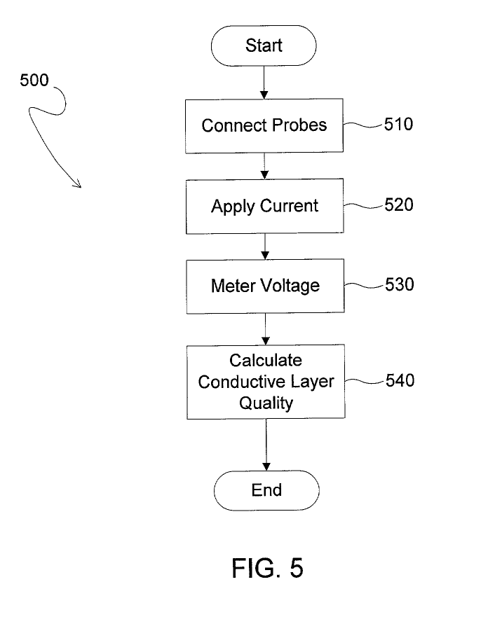

During conductive layer quality testing, electrical sourcing and metering unit 120 can apply a current to probe 155a, which is coupled to contact 1, via switching unit 125. The current can be collected by probe 155b, which is coupled to contact 2. Alternatively, electrical and sourcing unit 120 can apply current via probe 155b to contact 2 and collect current via probe 155a at contact 1. Further, during conductive layer quality testing, electrical sourcing and metering unit 120 can meter voltage between contacts 3 and 4 via probes 155c and 155d respectively. Electrical sourcing and metering unit 120 can then feed metered voltage and current data to control system 115 to calculate conductive layer quality, as will be discussed in further detail in conjunction with FIG. 5.

In another embodiment of the invention, a bottom conductive layer of cell 150 may be tested. Electrical sourcing and metering unit 120 can apply current to contact 5 on bus bar 230a via probe 155e and collect the current at contact 6 on bus bar 230b via probe 155f or vice versa. The electrical sourcing and metering unit can then also meter voltage at contact 7 on bus bar 230a and contact 8 on bus bar 230b using probes 155g and 155h respectively. Electrical sourcing and metering unit 120 can then feed metered voltage and current data to control system 115 to calculate conductive layer quality, as will be discussed in further detail in conjunction with FIG. 5.

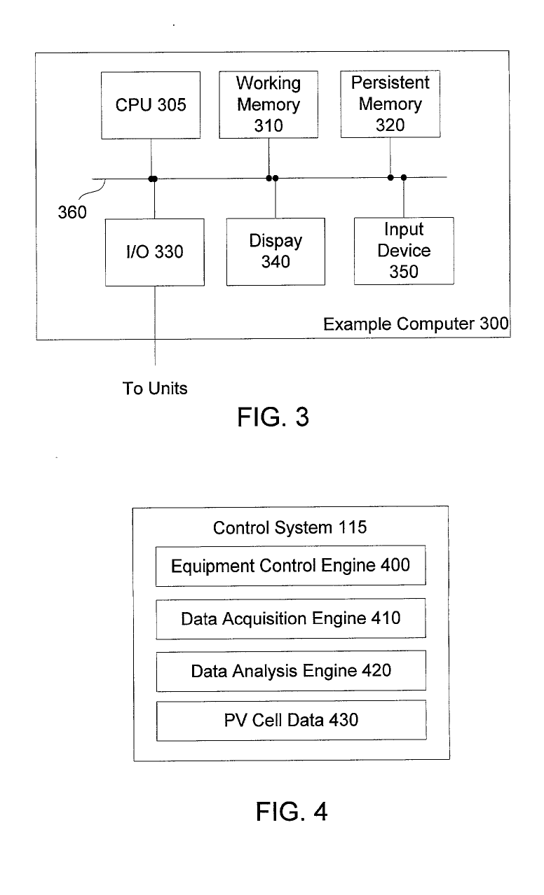

FIG. 3 is a block diagram illustrating an example computer 300 in accordance with the present invention. In an embodiment of the invention, conductive layer tester 110 may include or be resident on example computer 300. The example computer 300 includes a central processing unit (CPU) 305; working memory 310; persistent memory 320; input/output (I/O) interface 330; display 340 and input device 350, all communicatively coupled to each other via system bus 360. CPU 205 may include an Intel Pentium® microprocessor, a Motorola Power PC® microprocessor, or any other processor capable to execute software stored in persistent memory 320. Working memory 310 may include random access memory (RAM) or any other type of read/write memory devices or combination of memory devices. Persistent memory 320 may include a hard drive, read only memory (ROM) or any other type of memory device or combination of memory devices that can retain data after example computer 300 is shut off. I/O interface 330 is communicatively coupled, via wired or wireless techniques, to electrical sourcing and metering unit 120, switching unit 125, chamber 132, and cell handling unit 180, thereby enabling communications between example computer 300 and other devices.

Display 340 may include a cathode ray tube display or other display device. Input device 350 may include a keyboard, mouse, or other device for inputting data, or a combination of devices for inputting data.

One skilled in the art will recognize that the example computer 300 may also include additional devices, such as network connections, additional memory, additional processors, LANs, input/output lines for transferring information across a hardware channel, the Internet or an intranet, etc. One skilled in the art will also recognize that the programs and data may be received by and stored in the system in alternative ways.

FIG. 4 is a block diagram illustrating details of the control system 115 of the conductive layer quality tester 110 of the cell tester 100 (FIG. 1). Control system 115 comprises an equipment control engine 400, a data acquisition engine 410, a data analysis engine 420, and PV cell data 430. In an embodiment of the invention, engines 400, 410 and 420 may include software stored in persistent memory 320. In another embodiment of the invention, the engines 400, 410, and 420 may include integrated circuits, digital signal processors (DSPs) and/or other devices.

Equipment control engine 400 controls cell handling unit 180. In and embodiment of the invention, engine 400 can instruct cell handling unit 180 to couple probes 155 to cell 150 contacts and command electrical sourcing and metering unit 120 to apply current, via switching unit 125, to cell 150. Data acquisition engine 410 acquires applied current and metered voltage data from electrical sourcing and metering unit 120 during conductive layer quality testing.

Data analysis engine 420 analyzes data acquired by data acquisition engine 410 to calculate conductive layer quality. To calculate a top conductive layer quality, e.g., nominal number of broken conductive lines, engine 420 calculates resistance of the conductive layer as metered voltage divided by applied current, or more specifically, resistance equals the voltage difference at contacts 3 and 4 divided by current applied at contact 1 and collected at contact 2.

Based on the calculated resistance, analysis engine 420 can then calculate the number of conductive lines broken by looking up relevant data in PV cell data 430, which holds data on broken conductive lines for different calculated resistances for different cells. For example, for a 3.3 by 10 cm cell having 13 or more conductive lines, a resistance of Rᵢ/n Ohms indicates all lines are intact (wherein Rᵢ is the resistance of correctly formed conductive lines and n is the number of conductive lines), while the net resistance between the parallel combination of remaining unbroken conductive lines n may increase as Rᵢ/n as the number of effective current carrying lines are reduced by breakage. The calculated aggregate resistance may be high for other reasons (e.g., dimensional changes, material resistivity changes). A usefulness of analysis engine 420 is that it enables an operator to determine that resistivity of a cell is out of the bounds of a desired range for a process.

Similarly, for bottom conductive layers of PV cells, analysis engine 420 can calculate resistance as the difference in voltage at contacts 7 and 8 divided by the current applied at contacts 5 and collected as contact 6. As calculated resistance increases when conductive layer quality decreases, a high resistance would mean poor conductive layer quality and a low resistance would mean high conductive layer quality.

Accordingly, the resistance values measured by the analysis engine 420 may be used for statistical analysis, to determine that the conductive layer resistance is out of a pre-specified range, to determine if the conductive layer quality does not meet specified requirements and/or other purposes.

FIG. 5 is a flowchart illustrating a method 500 for measuring conductive layer quality of a PV cell, such as cell 150. First, probes are connected (510) to contacts on a PV cell. In an embodiment of the invention, equipment control engine 400 can command cell-handling unit 180 to connect (510) probes to contacts on a PV cell. In one embodiment, to measure top conductive layer quality of a cell, probe 155a can be coupled to contact 1, probe 155b can be coupled to contact 2, probe 155c can be coupled to contact 3, and probe 155d can be coupled to contact 4. In another embodiment, to measure bottom PV cell conductive layer quality, probe 155e can be coupled to contact 5, probe 155f can be coupled to contact 6, probe 155g can be coupled to contact 7, and probe 155h can be coupled to contact 8.

Next, current is applied (520) to a cell for conductive layer testing. In one embodiment of the invention, a current of 10⁻¹² Amps to 10³ Amps for 10⁻¹² seconds to 100 seconds is applied (520). In an embodiment of the invention, equipment control engine 400 can instruct electrical sourcing and metering unit 120 to apply a current, via switching unit 125, to contacts on a cell. For example, when measuring top conductive layer quality, current can be applied to contact 1 via probe 155a and collected at contact 2 via probe 155b or vice versa. When measuring a bottom conductive quality layer, current can be applied to contact 5 via probe 155e and collected at contact 6 via probe 155f, or vice versa.

While current is being applied (520), voltage is metered (530) between two contacts on the cell undergoing testing. In one embodiment, data acquisition engine 410 receives metered voltage data from the electrical sourcing and metering unit 120 when current is being applied to the cell. For a top conductive layer quality test, voltage can be metered at contact 3 via probe 155c and at contact 4 via probe 155d.

For a bottom conductive layer quality test, voltage can be metered at contact 7 via probe 155g and at contact 8 via probe 155h. After applying (520) current and metering (530) voltage, conductive layer quality is calculated (540). In an embodiment of the invention, data analysis engine 420 can perform the calculation based on metered voltage data acquired by data acquisition engine 410 and known current applied by equipment control engine 400. To calculate conductive layer quality, the difference in metered voltage between two contacts is divided by the applied current to yield conductive layer resistance. A conductive layer quality measurement, such as number of broken conductive lines, is then looked up in PV cell data 430, which lists conductive layer quality measurements for various resistances of various types of PV cells.

Alternatively, for a conductive layer comprising a continuous planar sheet of conductive material, quality, i.e., thickness of the conductive layer, can be calculated as t=ρl/Rw, wherein ρ is known resistivity of conductive material used in the conductive layer, l is the length of layer, R is the measured resistance, and w is the width of the layer. This technique, involving measuring resistance between the bus bars that typically span the width of a cell at two places is advantageous because the values of l and w are easily measured.

In an embodiment of the invention, method 500 may also comprise displaying the calculated conductive layer quality measurement on a display, such as display 340. Further, if the conductive layer of the cell does not meet a minimum quality calculation, the conductive layer may be reprinted and retested. Process conditions may be changed to bring the conductive layer quality (as determined by this measurement technique) to within a specified range. The method then ends.

In another embodiment of the invention, the method 500 can be used to determine if the calculated resistance falls outside of a specified range, thereby indicating a problem with the conductive layer and the need to repair the conductive layer (e.g., reprint the layer) or discard the cell.

The foregoing description of the preferred embodiments of the present invention is by way of example only, and other variations and modifications of the above-described embodiments and methods are possible in light of the foregoing teaching. For example, in an alternative embodiment of the invention to test conductive layer quality, a voltage potential may be applied to contacts on a PV cell and current may be measured concurrently instead of applying a current and measuring concurrent voltage. Further, components of this invention may be implemented using a programmed general purpose digital computer, using application specific integrated circuits, or using a network of interconnected conventional components and circuits. Connections may be wired, wireless, modem, etc. The embodiments described herein are not intended to be exhaustive or limiting. The present invention is limited only by the following claims.

What is claimed is:

1. A method, comprising:
applying a current to a conductive layer of a photovoltaic (PV) cell;
collecting the current from the conductive layer;
metering voltage on the conductive layer;
calculating resistance of the conductive layer based on the applied current and metered voltage; and
calculating conductive layer quality based on the calculated resistance.

2. The method of claim 1, wherein applying applies the current to the conductive layer via a contact on a first bus bar of the cell.

3. The method of claim 2, wherein collecting collects the current from the conductive layer via a contact on a second bus bar of the cell.

4. The method of claim 1, wherein metering meters the voltage across the conductive layer via a contact on a first bus bar of the cell and a contact on a second bus bar of the cell.

5. The method of claim 1, wherein the conductive layer is a conductive layer having a plurality of conductive lines.

6. The method of claim 5, wherein the calculating conductive layer quality comprises looking up conductive layer quality in a resistance vs. conductive layer quality file.

7. The method of claim 6, further comprising performing a corrective action if the determined conductive layer quality does not meet a specified range.

8. The method of claim 7, wherein the corrective action is selected from the group consisting of reprinting the conductive layer, reforming the conductive layer, and modifying process conditions to bring the resistance of the conductive layer to within a specified range.

9. The method of claim 1, wherein the conductive layer is a conductive layer having a conductive sheet.

10. The method of claim 9, further comprising calculating a thickness of the conductive layer based on the calculated resistance, a known length of the layer, a known width of the layer, and a known resistivity of conductive material used in the layer.

11. A computer-readable medium storing instructions to cause a computer to:
send a command to an electrical sourcing and metering unit to apply a current to a conductive layer of a photovoltaic (PV) cell and to collect the current from the conductive layer;
receive voltage metering data from the electrical sourcing and metering unit coupled to the conductive layer;
calculate resistance of the conductive layer based on the applied current and the voltage metering data; and.
calculate conductive layer quality based on the calculated resistance.

12. The computer-readable medium of claim 11, wherein the instruction to send a command to apply and collect includes applying the current to the conductive layer via a contact on a first bus bar of the cell.

13. The computer-readable medium of claim 12, wherein the instruction to send a command to apply and collect includes collecting the current from the conductive layer via a contact on a second bus bar of the cell.

14. The computer-readable medium of claim 11, wherein the instruction to receive receives metered voltage from the conductive layer via a contact on a first bus bar of the cell and a contact on a second bus bar of the cell.

15. The computer-readable medium of claim 11, wherein the conductive layer is a conductive layer having a plurality of conductive lines.

16. The computer-readable medium of claim 11, wherein the instruction to calculate conductive layer quality comprises looking up conductive layer quality in a resistance vs. conductive layer quality file to determine conductive layer quality.

17. The computer-readable medium of claim 16, further comprising an instruction to perform a corrective action if the determined conductive layer quality does not meet a specified range.

18. The computer-readable medium of claim 17, wherein the corrective action is selected from a group consisting of reprinting the conductive layer, reforming the conductive layer, and modifying process conditions.

19. The computer-readable medium of claim 11, wherein the conductive layer is a conductive layer having a conductive sheet.

20. The computer-readable medium of claim 19, further comprising an instruction to calculate a thickness of the conductive layer based on the calculated resistance, a known length of the layer, a known width of the layer, and a known resistivity of conductive material used in the layer.

21. A system, comprising:
means for applying a current to a conductive layer of a photovoltaic (PV) cell;
means for collecting the current from the conductive layer;
means for metering voltage on the conductive layer;
means for calculating resistance of the conductive layer based on the applied current and metered voltage; and
means for calculating conductive layer quality based on the calculated resistance.

22. A system, comprising:
an electrical sourcing and metering unit capable to be coupled to a conductive layer of a photovoltaic cell, the electrical sourcing and metering unit further capable to apply current to the layer, collect the applied current, and meter voltage across the conductive layer; and
a conductive layer quality tester, communicatively coupled to the electrical sourcing and metering unit, the tester including
an equipment control engine capable to instruct the electrical sourcing and metering unit to apply current and collect current from the conductive layer and to meter voltage across the layer,
a data acquisition engine capable to receive applied current and metered voltage data from the electrical sourcing and metering unit, and
a data analysis engine capable to calculate resistance of the conductive layer based on applied current and metered voltage, and to calculate conductive layer quality based on the calculated resistance.

23. The system of claim 22, wherein the electrical sourcing and metering unit applies the current to the conductive layer via a contact on a first bus bar of the cell.

24. The system of claim 23, wherein electrical sourcing and metering unit collects the current from the conductive layer via a contact on a second bus bar of the cell.

25. The system of claim 22, wherein the data acquisition engine is further capable to receive metered voltage from the conductive layer via a contact on a first bus bar of the cell and a contact on a second bus bar of the cell.

26. The system of claim 22, wherein the conductive layer is a conductive layer having a plurality of conductive lines.

27. The system of claim 22, wherein the data analysis engine calculates conductive layer quality by looking up conductive layer quality in a resistance vs. conductive layer quality file.

28. The system of claim 22, wherein the conductive layer is a conductive layer having a conductive sheet.

29. The system of claim 28, wherein the data analysis engine is further capable to calculate a thickness of the conductive layer based on the calculated resistance, a known length of the layer, a known width of the layer, and a known resistivity of conductive material used in the layer.

30. The system of claim 22, wherein the system is incorporated into an illuminated IV cell tester.

31. A method, comprising:
applying a voltage potential to a conductive layer of a photovoltaic (PV) cell;
measuring current across the layer during application of the voltage potential;
calculating resistance of the conductive layer based on the current and applied voltage potential; and
calculating conductive layer quality based on the calculated resistance.

32. A system, comprising:
an electrical sourcing and metering unit capable to be coupled to a conductive layer of a photovoltaic cell, the electrical sourcing and metering unit further capable to apply a voltage potential to the layer, and measure current across the conductive layer; and
a conductive layer quality tester, communicatively coupled to the electrical sourcing and metering unit, the tester comprising
an equipment control engine capable to instruct the electrical sourcing and metering unit to apply a voltage potential to the conductive layer and to measure current across the layer,
a data acquisition engine capable to receive measured current and applied voltage potential data from the electrical sourcing and metering unit, and
a data analysis engine capable to calculate resistance of the conductive layer based on the measured current and applied voltage potential, and to calculate conductive layer quality based on the calculated resistance.

33. An integrated light IV cell tester/cell conductive layer quality tester, comprising:
means for performing an illuminated IV cell test;
an electrical sourcing and metering unit capable to be coupled to a conductive layer(s) of a photovoltaic cell, the electrical sourcing and metering unit further capable to apply current to the layer(s), collect the applied current, and meter voltage across the conductive layer; and
a conductive layer quality tester, communicatively coupled to the electrical sourcing and metering unit, the tester including
an equipment control engine capable to instruct the electrical sourcing and metering unit to apply current and collect current from the conductive layer(s) and to meter voltage across the layer(s),
a data acquisition engine capable to receive applied current and metered voltage data from the electrical sourcing and metering unit, and
a data analysis engine capable to calculate resistance of the conductive layer(s) based on applied current and metered voltage, and to calculate conductive layer quality based on the calculated resistance.
